(19) United States
(12) Patent Application Publication
(10) Pub. No.: US 2025/0160039 A1
(43) Pub. Date: May 15, 2025

(54) FABRICATION OF GRAPHENE-BASED ELECTRODES WITH ULTRA-SHORT CHANNEL

(71) Applicants: Keren SHUSHAN, Tel Aviv (IL); RAMOT AT TEL-AVIV UNIVERSITY LTD., Tel Aviv (IL)

(72) Inventors: Ariel ISMACH, Tel Aviv (IL); Kamalakannan RANGANATHAN, Tel Aviv (IL); Assael COHEN, Tel Aviv (IL); Pranab Kishore MOHAPATRA, Tel Aviv (IL)

(21) Appl. No.: 18/838,016

(22) PCT Filed: Feb. 16, 2023
(86) PCT No.: PCT/IL2023/050161

§ 371 Date: Aug. 13, 2024

Related U.S. Application Data
(60) Provisional application No. 63/311,079, filed on Feb. 17, 2022.

(51) Int. Cl. H10F 71/00; H10F 77/12

(52) U.S. Cl. CPC H10F 71/1385; H10F 71/125; H10F 77/127

(57) ABSTRACT

The technology disclosed herein concerns a process for fabricating devices with Graphene Nanogap Electrodes (GNE).

### TECHNOLOGICAL FIELD

The invention generally contemplates method for fabricating devices with Graphene Nanogap Electrodes (GNE).

### BACKGROUND

Nanofabrication represents one of the most important features of modern electronics, optoelectronics, photonics and information technologies. Nanofabrication requires the introduction of unconventional techniques for material patterning to make functional structures. One of the key processes in the fabrication of functional structures is lithography. However, the nanofabrication of structures smaller than 20 nm is cumbersome, expensive, time consuming, typically available mainly to big industrial companies or to research centers, hence, not reachable to the vast majority of research groups and small R&D companies, hence, a suitable replacement for lithography is yet to be developed.

Owing to its excellent properties, including excellent electrical and thermal conductivities, good mechanical strength and high specific surface area, graphene has been regarded as an ideal component in the fabrication of electrode materials in the fields of nanoelectronics (and optoelectronics), flexible electronics (and optoelectronics), energy conversion and storage and sensors. A graphene field effect transistor (GFET) is typically composed of a graphene channel between two electrodes with a gate contact to modulate the electronic response of the channel. In such configurations, the graphene is exposed to enable functionalization and binding of target-specific receptor molecules to the channel surface. By forming direct association between the graphene structure and the receptor or ligand molecules, structural properties of the graphene may be damaged leading to a reduction in the device sensitivity (in particular, the high carrier mobility and favorable noise characteristics).

### GENERAL DESCRIPTION

The inventors of the technology disclosed herein have developed a novel methodology for the fabrication of nanogap electrodes (from few to 100s of nanometers) without the need for complex lithographic processes, such as that demonstrated for the purpose of comparison in FIG. 1. This could be used for efficient fabrication of transistors, such as field effect transistors (FETs), that comprise a source electrode and a drain electrode, each made of a single-layer or a few-layer graphene, separable by a channel comprising at least one active material (electronically active materials, e.g., materials demonstrating carrier mobility). FETs are devices that could be used in a wide range of applications such as nanoelectronics (and optoelectronics), flexible electronics (and optoelectronics), and sensors. Unlike methodologies used in the art, the channel separating the source and drain is fabricated by catalytic etching of a pre-patterned graphene micro- or nanostrip utilizing metal or metal oxide nanomaterials (such as nanowires, nanorods or nanoparticles). The conditions utilized in the etching of the graphene micro- or nanostrip provide control over the profile of the channel, namely the channel width, length and depth, and thus on the device performance, and provided atomically smooth graphene edges, not possible to achieve by any other methodology.

Thus, in its broadest aspect the invention provides a device comprising a graphene electrode assembly including a source electrode and a drain electrode (or a device comprising two electrodes), each comprising or consisting a single-layer or a few-layer graphene, the source electrode and drain electrode being spatially separated by a nano-channel gap formed by a nanomaterial (nanowire, nanorod or nanoparticle)-induced etching of a graphene surface. The nano-channel size formed by the catalytic etching depends on the nanomaterial used (e.g., its chemical composition such as metal or metal oxide), structure (e.g., nanowire, nanorod or nanoparticle) and size, as well as on the catalytic etching procedure conditions (such as temperature, time and gas composition).

The invention further provides a short channel transistor comprising a source electrode and a drain electrode, each of the source and drain electrodes comprising or consisting a single-layer or a few-layer graphene and an etched nanogap disposed between the electrodes, the nanogap having a width ranging between a single nanometer to few tens of nanometers (e.g., 1 nm to 100 nm), and comprising an active material.

Further provided is a transistor device comprising a source electrode and a drain electrode spatially separated by an etched nanogap of a width ranging between a single nanometer to few tens of nanometers, wherein said nanogap volume comprising an active material.

The gap created by the catalytic etching process can be filled by a wide range of active materials such as different inorganic and organic nanostructures (0, and 1D), films (2D) and crystals (3D). The graphene electrodes are highly chemical and thermal resistant and therefore compatible with a wide range of nanomaterial deposition methodologies in liquid solutions (such as electrophoresis, colloidal growth, etc.) and gas phase deposition (physical and chemical vapor deposition, PVD and CVD, respectively as well as atomic layer deposition). One example of an active material is a transition metal dichalcogenide (TMDC, e.g., deposited using metal-organic chemical vapor deposition, MOCVD, at 400° C.).

Further provided is a field effect transistor device comprising a source electrode and a drain electrode, each comprising or consisting a single-layer or a few-layer graphene and a channel of an active material filling a nanogap disposed between the graphene electrodes, wherein the distance between the electrodes with a length ranging between at least a single nanometer to at least few tens of nanometer.

The invention further provides a nanofabricated transistor device, the device comprising at least two longitudinally oriented graphene segments, each segment having at least one end proximal to an end of another graphene segment, wherein the gap or distance between each two proximate ends is a nanogap, wherein the nanogap is formed by nanomaterial—(e.g., nanoparticle-) induced etching and wherein the nanogap comprising an active material such as transition metal dichalcogenides (TMDC), as well as other thin films and nanomaterials (0, 1 and 2D).

The device of the invention comprises graphene nanogap electrodes wherein a first electrode and a second electrode are arranged opposite to each other on the substrate at a distance that is in the nanometric scale (between 1 and 100 nm). The device may comprise one or more first electrodes and one or more second electrodes each second electrode is arranged opposite to each first electrode, wherein a nanomaterial or nanoparticles-induce nanogap or a channel is provided between each first electrode and the second electrode opposite thereto, the nanogap or channel having a profile defined by a nanoparticle forming the nanogap.

Devices of the invention are structures comprising at least one pair of “Graphene Nanogap Electrodes”, which substantially comprises a semiconductor material having a bounding surface, which under the influence of an electrical field, can amplify or rectify electric signals. In devices of the invention, both the drain and source electrodes are composed or made of graphene, and are separated from each other across a separating gate or a channel which is graphene free and which comprises or consists an active material such as a transition metal dichalcogenide (TMDC). As with other transistor devices, the device is formed on a substrate such as a silicon substrate (or any other alternative substrate materials such as GaAs, CdTe, and copper indium gallium selenide (CIGS)) of the form shown in the embodiment depicted in FIG. 2.

In some configurations, the transistor is structured as a field effect transistor, FET, device, as known in the art.

The invention further provides a nanofabrication process for fabricating a device comprising an ultra-short gap between the electrodes (namely the distance between the two electrodes is ultra-short, or is between 1 and 100 nm), the process comprising forming a lateral channel in a graphene strip (being a nanostrip or a microstrip) by a nanomaterial or nanoparticle-induced catalytic etching.

In some embodiments, the process comprises
forming a graphene strip on a substrate material, such as SiO₂/Si;
structuring a lateral channel in the graphene strip by a nanomaterial or a nanoparticle-induced etching of the strip; and
depositing in said channel an active material such as a transition metal dichalcogenide (TMDC) material.

The graphene used for fabricating the source and drain electrodes is single-layer graphene, namely an atomic layer of graphene, or is or comprises of a few layers of graphene, namely between 2 and 10 layers of graphene. Generally speaking, atomic layers of graphene can be fabricated by various methods such as mechanical exfoliation of graphite, deposition of epitaxial graphene on SiC crystals, and chemical vapor deposition of graphene using metal catalysts. One of the methods is mechanical exfoliation, in which graphene layers are peeled repeatedly using a scotch-tape technique to achieve a single-layer or a few-layer graphene that could then be transferred to arbitrary substrates. The number of graphene layers can be easily identified using optical microscopy due to a contrast in a certain oxide layer thickness. For mass production, epitaxial graphene can be formed directly on an insulating substrate by sublimating silicon atoms at high temperatures and low pressures, preventing need for the transfer process. The growth of large-area graphene is favorable for wafer-scaled lithography, which can be formed by chemical vapor deposition methods. The carbon atoms are supplied by hydrocarbon materials and dissolved on a metal surface and then transferred to an insulating wafer.

As further explained herein, devices of the invention are fabricated from graphene strips, which may microstrips or nanostrips of graphene having, typically, widths of 2 to 20 μm. The fabrication of narrower strips of graphene may be achieved using e-beam lithography. Other lithography methods based on atomic force microscopy and scanning tunneling microscopy (STM) can be used in the fabrication of the graphene microstrip. Additional methodologies may involve unzipping of carbon nanotubes (CNTs) such as single walled CNTs or multiwalled CNTs (MWCNTs) as precursors.

In a fabrication process of a device of the invention, a single-layer or a few-layer or a multi-layer graphene may be first formed or synthesized by any means known in the art, or may be commercially obtained from available sources. In some configurations, a low-pressure chemical vapor deposition (LPCVD) technique may be utilized, involving copper/nickel foil as a catalytic surface in the presence of methane, in a controllable environment at high temperatures. The ‘as grown’ graphene samples formed on the metal foil may be transferred onto a substrate by a standard polymethyl methacrylate (PMMA) transfer technique.

An exemplary PMMA transfer technique may involve spin-coating PMMA on a synthesized graphene surface formed on a metal foil such as copper or nickel, etching away the metal surface to obtain PMMA/graphene membrane and transferring the membrane onto a silicon-based surface (i.e., SiO₂/Si) of a type used to fabricate the device. The PMMA may thereafter be removed by using a solvent such as acetone, thereby obtaining a graphene layer directly provided on the SiO₂/Si substrate. This may be followed by a standard photolithography and an etching step to fabricate the graphene (single-, few- or multi-layer) strips. The surface morphology of the fabricated strip may be characterized by high resolution scanning electron microscope (HRSEM) and atomic force microscopy (AFM) measurements.

Once the graphene strips have been fabricated on a substrate such as a silicon-based substrate, the device electrode assembly may be formed. According to the novel methodology disclosed herein, the graphene strip, e.g., microstrip, is transformed into source and drain electrodes by causing a lateral discontinuity in the strip, namely by forming a lateral gap along the microstrip that is substantially perpendicular to the length (or long axis, or any predefined or desired axis) of the graphene strip.

By causing the discontinuity, two longitudinally oriented graphene segments are obtained, wherein each segment has at least one end proximal to an end of another graphene segment. Typically, the two ends facing each other, originate from a single continuous graphene strip or microstrip. However, in some embodiments, the two graphene segments may be arranged parallel to each other, or arranged not on the same axis. Notwithstanding, the relative orientation of the two segment ends, the gap or distance between each two proximate ends is a single atom to few atoms, or is as disclosed herein.

Discontinuity or lateral etching is achieved by a nanomaterial-induced or more specifically a nanoparticle-induce catalytic etching using a nanomaterial or a nanostructure, such as a metallic nanomaterial selected as defined herein. The term “catalytic etching” refers to a preferential and directional etching technique using a catalyst, such as a metal catalyst, that forms controlled micro- or nano-scratches or drenches or channels in the graphene layer. The micro- or nano-structuring is possible due to the formation of etch track pores of roughly a size that is a diameter size of the nanomaterial or nanoparticle, e.g., a metal nanoparticle, used for fabricating the micro- or nanostructures. These etch tracks are typically straight or substantially straight, namely a line pattern that is typically without a bend, an angle, or a curvature, and which extends a shortest distance or a distance that is within 10-30% of a shortest distance between point of origin and an end point.

Nanogaps or channels formed according to methods of the invention are solely achieved by catalytic etching. In other words, structuring or forming a nanogap or a channel in a graphene strip, e.g., a microstrip, to obtain a pair of electrodes separated by the nanogap or the channel, as disclosed herein, consists “nanomaterial-induced catalytic etching”, namely structuring caused solely by catalytic etching and excludes methods such as lithography, electron beam etching and others.

In most general terms, the catalyst being, for example a metal or a metal oxide nanomaterial, typically a nanoparticle that is deposited on the graphene strip under conditions permitting etching the graphene material at the interface between the graphene and the nanomaterial, leaving behind a nanogap or a trench or a channel of a profile, i.e., width and depth, defined by the conditions employed (e.g., temperature of exposure, time of exposure and gases present) and type/size of nanomaterial utilized. In principle, many nanomaterial compounds can be used by tailoring the chemistry to achieve local gasification (catalytic etching) of the graphene. Nanomaterials including metal halides and sulfides (or metal chalcogenides in general), carbon halides and carbon chalcogens may also be used.

In some configurations, the nanomaterial may exhibit or may be caused to exhibit a substantially lateral movement across the graphene strip, etching the graphene along its path.

The metal nanomaterial used for the catalytic etching may be composed of any metal, metal alloy or metal oxide. Non-limiting examples include copper, nickel, aluminum, iron, silver, gold, SiO₂, ZrO₂, and others. The nanomaterial may be any nanoparticle of any shape and size. However, as the nanomaterials shape and size contribute to the depth and width of the nanogap formed, spherical nanoparticles may be used, with diameters depending on the number of atoms in the nanoparticle. 1D nanostructures such as nanorods, nanotubes and nanowires may also be used. In some cases, a plurality of nanoparticles may be used.

In some embodiments, the nanoparticles are selected based on the number of atoms they comprise. The number of atoms may range from few tens of atoms to few hundred of atoms, e.g., between 30 and 1000 atoms. As the number of atoms cannot always be determined, the nanoparticles used may be selected based on their diameter being, for example, between 1 and 100 nm. In some embodiments, the nanoparticle used is of a size between 1 and 100 nm, 1 and 90 nm, 1 and 80 nm, 1 and 70 nm, 1 and 60 nm, 1 and 50 nm, 1 and 40 nm, 1 and 30 nm, 1 and 20 nm, 1 and 10 nm, 10 and 100 nm, 10 and 90 nm, 10 and 80 nm, 10 and 70 nm, 10 and 60 nm, 10 and 50 nm, 10 and 40 nm, 20 and 100 nm, 30 and 100 nm, 40 and 100 nm, 50 and 100 nm, 60 and 100 nm, 70 and 100 nm, 80 and 100 nm, or 90 and 100 nm.

In some embodiments, the length and/or width of the nanoparticle is between 1 and 100 nm. In some embodiments, the length and/or width is between 1 and 100 nm, 1 and 90 nm, 1 and 80 nm, 1 and 70 nm, 1 and 60 nm, 1 and 50 nm, 1 and 40 nm, 1 and 30 nm, 1 and 20 nm, 1 and 10 nm, 10 and 100 nm, 10 and 90 nm, 10 and 80 nm, 10 and 70 nm, 10 and 60 nm, 10 and 50 nm, 10 and 40 nm, 20 and 100 nm, 30 and 100 nm, 40 and 100 nm, 50 and 100 nm, 60 and 100 nm, 70 and 100 nm, 80 and 100 nm, or 90 and 100 nm.

Apart from spherical nanoparticles, 1D materials such as nanorods, nanotubes, nanowires and other non-spherical nanomaterials may be utilized. In cases 1D nanomaterials or nanostructures are used, the material may be oriented using a gas flow, such as N₂ flow, liquid droplets or dispersions or gas phase. Also, in such cases, the 1D nanomaterial may be deposited perpendicular to the main axis of the pre-patterned graphene stripe (FIG. 3).

Catalytic etching of multilayered graphene and single layer graphene is possible also along specific crystallographic directions, as reported, for example in Nano Lett., 2009, 9, 7, 2600 or J. Phys. Chem., 1974, 78, 22, 2254.

A metallic nanomaterial or nanostructure, such as a metal nanoparticle and nanowire, may be deposited on the graphene strip or microstrip or in the vicinity thereof and the surface may be then heated to a temperature ranging between 350° C. and 600° C., e.g., at a rate of about 0.5 m/sec, over a period of time (few minutes), in the presence of air or hydrogen/argon gas (depending on the material used), causing the nanostructure etch the graphene material at any point of contact or interface between the nanostructure and the graphene. Alternatively, a metal precursor solution, e.g., a metal salt, is deposited onto the surface of the graphene strip or in its vicinity and the metal precursor is thermally treated to generate the corresponding metal/metal oxide nanoparticles.

In some embodiments, etching is achievable at a temperature between 350 and 600° C., e.g., in presence of hydrogen gas. In some embodiments, the temperature is between 350 and 600° C., 400 and 600° C., 450 and 600° C., 500 and 600° C., 550 and 600° C., 350 and 500° C., or between 400 and 500° C.

In some embodiments, thermal treatment at a temperature above ˜500° C., over a period of time, in the presence of hydrogen gas, brings about nanostructure mobility and etching.

Thus, in further embodiments, a process of the invention comprises treating a graphene strip, e.g., a microstrip, having at least one metallic nanoparticle provided on an edge region of the strip, at a temperature between 350 and 600° C., optionally under an atmosphere of hydrogen gas, to cause local gasification of the graphene at the interface with the nanomaterial.

In some embodiments, the strip is a microstrip.

In some embodiments, the process comprises
obtaining or forming a graphene microstrip on a substrate material, such as SiO₂/Si; and
heating the microstrip to a temperature between 350° C. and 600° C. to induce etching of the microstrip at an interface with the nanomaterial.

In some embodiments, the process comprises
obtaining or forming a graphene microstrip on a substrate material, such as SiO₂/Si;
depositing the catalytic nanomaterial; and
heating the microstrip to a temperature between 350° C. and 600° C. to induce a local gasification of the graphene at the interface with the nanomaterial (the catalytic etching process).

Without wishing to be bound by theory, during the high temperature etching stage, the metal nanoparticle etches the graphene through catalytic oxidation or hydrogenation of carbon atoms which are in contact with the metal nanoparticle. This causes local evaporation of the carbon atoms by formation of CO/CO₂ or CHₓ gases, depending on the nanomaterial, gaseous environment and temperature used.

In some cases, the metal nanostructures or the metal precursor solution is deposited on the graphene strip by electron beam evaporation or by drop-casting the dispersion or solution, respectively, followed by annealing under mild temperatures, typically ˜350-600° C.

Following fabrication of the nanogap or channel or the discontinuity, as defined herein, the etchant nanomaterials or nanostructures may be selectively removed from the graphene film by any means known in the art, e.g., by wet etching with an iodine-HCl solution, without damaging the graphene surface.

As noted above, the conditions utilized in the etching step provide control over the profile of the trench formed, e.g., width, length and depth.

In most general terms, the profile of the trench, namely its depth and width, remains substantially constant along its length. In some embodiments, the depth of the trench and the width of the trench, independently, are single to several or nanometers in size. In other words, selective and carefully designed etching can provide trenches with depth and widths that are 1 and 100 nm or between 5 nm to 100 nm in size. In some cases, the width or depth of the trench formed is between 10 and 60 nm or between 20 and 50 nm or between 20 and 40 nm. The length, depth and width of the trench may be characterized as a function of the annealing temperature, etching time and the size of the silver nanostructures by AFM and HRSEM.

Once the lateral discontinuity or nanogap is formed in the graphene strip, the nanogap may be filled up or covered with a variety of active materials, thin films, 2D materials (such as transition metal dichalcogenide (TMDC)), 1D materials (such as nanowires and nanotubes) and 0D materials (quantum dots and nanoparticles). In some embodiments, the active material is a transition metal dichalcogenide (TMDC) material. Due to shallowness of the trench, i.e., being at times a single atom or few atoms deep, the TMDC may be monolayer thick. The TMDC may be deposited by any available technique, such as chemical vapor deposition (CVD) and metal organic chemical vapor deposition techniques (MOCVD).

The TMDC may be selected amongst semiconductor materials of the type MX₂, wherein M is a transition-metal atom, such as Mo and W, and X is a chalcogen atom selected amongst S, Se or Te. In a deposited monolayer of TMDC, one layer of the transition metal atoms is sandwiched between two layers of the chalcogenide atoms. The TMDC may be selected from MoS₂, WS₂, MoSe₂, WSe₂, MoTe₂ and others, each deposited via any available CVD technique directly onto the trench, to form the channel material.

To complete the transistor device, metal contacts may be formed by PVD deposition and the device may be further manipulated to obtain a fully operable device.

The methodology of the invention provides a relatively simple way to fabricate ultra-small channel devices, without the need of complex lithographic processing. Devices based on the graphene nanogap electrodes of the invention may be, but not restricted to, sensors, electrical, electromechanical or optical switches, quantum devices (such as single-electron transistors), etc.

In some embodiments, devices of the invention may be formed into sensor devices usable in such application as electrical and opto-electronic characterization of nanomaterials and molecules and in photodetectors and sensors. Furthermore, thanks to the high flexibility of single- and few-layer graphene films, nanogap electrodes of the invention may be used in flexible electronics/optoelectronic devices.

For example, a device of the invention is a photodetector. As disclosed herein, a photodetector was fabricated by directly depositing a WS₂, at a relatively low temperature, on the graphene nanogap electrodes with channel lengths of 70, 180 and 540 nm, demonstrating that the performance of the photodetector is improved when the channel length reduced.

The invention further provides a device comprising a graphene electrode assembly including a source electrode and a drain electrode, each comprising or consisting a single-layer or a few-layer graphene, the source electrode and drain electrode spatially separated by a nanogap formed by a nanomaterial-induced etching of a graphene surface.

In devices of the invention, the nanogap may have a width ranging between 1 nm and 100 nm.

In devices of the invention, the nanogap may comprise an active material.

In devices of the invention, a pair of metal electrodes may be provided.

In devices of the invention, the devices may be field effect transistors.

A short channel transistor device comprising a source electrode and a drain electrode, each of the source and drain electrodes comprising or consisting a single-layer or a few-layer graphene; an etched nanogap disposed between the electrodes having a width ranging between 1 nm and 100 nm and comprising an active material.

A transistor device comprising a source electrode and a drain electrode spatially separated by an etched nanogap of a width ranging between 1 and 100 nanometers, said nanogap having a volume comprising an active material, wherein each of the electrodes comprising or consisting a single-layer or a few-layer graphene.

In devices of the invention, the device may be a nanofabricated transistor device comprising at least two longitudinally oriented graphene segments, each segment having at least one end proximal to an end of another graphene segment, wherein the gap or distance between each two proximate ends is a nanogap, wherein the nanogap is formed by the nanomaterial-induced etching and wherein the nanogap comprising a transition metal dichalcogenide.

In devices of the invention, a first electrode and a second electrode may be arranged opposite to each other on a substrate at a nanometric distance.

In devices of the invention, fabricated by a process which may comprise forming a lateral channel in a graphene strip by the nanomaterial-induced catalytic etching, the channel being a nanogap.

In devices of the invention, the graphene strip may be a nanostrip or a microstrip.

In devices of the invention, the devices may be formed by a process comprising
forming a graphene strip on a substrate material;
forming the lateral channel in the graphene strip by the nanomaterial-induced etching of the strip; and
depositing in said channel an active material.

In devices of the invention, the devices may be formed on a silicon-based substrate.

In devices of the invention, the nanogap may have a depth and/or width of a size between 1 and 100 nm.

In devices of the invention, depth and/or width of the nanogap may be between 5 nm to 100 nm, 10 and 60 nm, 20 and 50 nm, or 20 and 40 nm.

In devices of the invention, the nanogap may comprise an active material in a form of a thin film.

In devices of the invention, the active material may be selected from 2D materials, 1D materials and 0D materials.

In devices of the invention, the 2D material may be a transition metal dichalcogenide (TMDC).

In devices of the invention, the TMDC may be a semiconductor material of the form MX₂, wherein M is a transition-metal atom and X is a chalcogen atom.

In devices of the invention, wherein M may be Mo or W.

In devices of the invention, wherein X may be S, Se or Te.

In devices of the invention, the TMDC may be selected from MoS₂, WS₂, MoSe₂, WSe₂, and MoTe₂.

In devices of the invention, the 1D active material may be a form of a nanowire or a nanotube.

In devices of the invention, the 0D active material may be a quantum dot or a nanoparticle.

In devices of the invention, devices may comprise a graphene source electrode and a graphene drain electrode spatially separated by channel comprising at least one active material selected from MoS₂, WS₂, MoSe₂, WSe₂, and MoTe₂.

In devices of the invention, the graphene source and drain electrodes may comprise each a metal electrode.

In devices of the invention, each of the graphene electrodes may have atomically smooth graphene edges.

A process for fabricating a device comprising an ultra-short gap between a pair of electrodes, each electrode comprising or consisting a single-layer or a few-layer graphene, the process comprising forming a lateral channel in a graphene strip being a single-layer or a few-layer graphene strip, wherein the channel is formed by a nanomaterial-induced catalytic etching.

In processes of the invention, the process may comprise
forming a graphene strip on a substrate material,
forming the lateral channel in the graphene strip by a nanomaterial-induced etching of the strip; and
depositing in said channel an active material.

In processes of the invention, the substrate may be a SiO₂/Si substrate.

In processes of the invention, the active material may be a transition metal dichalcogenide (TMDC).

In processes of the invention, the graphene strip may comprise between 2 and 10 layers of graphene.

In processes of the invention, the graphene strip may be formed by mechanical exfoliation of graphite, deposition of epitaxial graphene on SiC crystals, or chemical vapor deposition of graphene.

In processes of the invention, the graphene strip may be formed on a metal foil and transferred onto a substrate by a polymethyl methacrylate (PMMA) transfer technique.

In processes of the invention, the graphene strip may have a width of 2 to 20 μm.

In processes of the invention, the graphene strip may be a nanostrip or a microstrip.

In processes of the invention, forming the lateral channel may comprise placing a nanoparticle catalyst on the graphene strip under conditions permitting its substantially lateral movement across the graphene strip, etching the graphene material along its path.

In processes of the invention, forming the lateral channel may comprise placing a nanoparticle catalyst on the graphene strip under conditions permitting etching the graphene material at any point of interface with the nanomaterial.

In processes of the invention, the nanoparticle catalyst may be a metal, a metal oxide, a metal alloy, a metal halide, a metal chalcogenide, a carbon halide or a carbon chalcogen nanomaterial.

In processes of the invention, the nanogap may have a profile defined by a type and/or size of the nanomaterial.

In processes of the invention, the catalyst may be a metal or a metal oxide nanoparticle.

In processes of the invention, the metal nanomaterial comprises a metal selected from copper, nickel, aluminum, iron, silver, gold, zirconium.

In processes of the invention, the metal nanomaterial may be a metal oxide selected from copper oxides, nickel oxides, aluminum oxides, iron oxides, silver oxides, gold oxides, SiO₂, and ZrO₂.

In processes of the invention, the nanomaterial-induced catalytic etching may comprise at least one nanoparticle selected from a spherical nanoparticle, a nanorod, a nanotube and a nanowire.

In processes of the invention, the nanoparticle may comprise between 30 and 1000 atoms.

In processes of the invention, the nanoparticles may have a diameter, a width and/or a length between 1 and 100 nm.

In processes of the invention, the processes may comprise depositing on the graphene strip or in a vicinity thereof a nanoparticle and subsequently heating the strip to a temperature between 350° C. and 600° C., in presence of air or hydrogen/argon gas, to thereby cause etching of the graphene material.

In processes of the invention, the strip may be heated to a temperature above 500° C., in the presence of hydrogen gas.

In processes of the invention, the processes may comprise treating a graphene microstrip, having at least one metallic nanoparticle provided on an edge region of the strip, at a temperature between 350 and 600° C., under an atmosphere of hydrogen gas, to cause local gasification of the graphene at the interface with the nanomaterial.

In processes of the invention, the nanogap may have a depth or a width of a size between 1 and 100 nm.

In processes of the invention, the processes may comprise depositing in the nanogap an active material or a thin film formed of a 2D material, a 1D material or a 0D material.

In processes of the invention, the 2D material may be a transition metal dichalcogenide (TMDC) material.

In processes of the invention, the TMDC may be deposited by chemical vapor deposition (CVD) or metal organic chemical vapor deposition (MOCVD).

In processes of the invention, the TMDC may be a semiconductor material of the form MX₂, wherein M is a transition-metal atom, and X is a chalcogen atom.

In processes of the invention, the TMDC may be selected from MoS₂, WS₂, MoSe₂, WSe₂, and MoTe₂.

In processes of the invention, being for forming a channel device comprising a pair of graphene nanogap electrodes, the electrodes being spatially separated by a nanogap formed by a metal or a metal oxide nanoparticle-induced etching of a graphene surface.

In processes of the invention, the device formed is a photodetector or a sensor.

A photodetector comprising a pair of graphene nanogap electrodes, the electrodes being spatially separated by a nanogap formed by a nanomaterial-induced etching of a graphene surface.

In devices of the invention, the devices may have a WS₂ nanogap with a length of 70, 180 and 540 nm.

A device comprising a photodetector according to the invention.

A sensor device comprising a photodetector according to the invention.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 provides a schematic representation of the graphene micro- or nano-strip fabrication by standard lithography (prior art).

FIG. 2 is a schematic representation of the nanogap electrode fabrication process according to some embodiments of the invention: pre-patterned graphene stripes on which metal nanowires (or metal oxide, in this embodiment, such as silver nanowires) are dispersed perpendicularly to the main axis of the stripes. Catalytic etching of the graphene underneath the nanowires is carried out by fast heating the sample in air. Metal electrodes are patterned by standard lithography.

FIG. 3 provides in-situ electrical measurements while performing catalytic etching: From left to right: SEM image of a graphene stripe (dark) connected between two Au source and drain electrodes (bright). An Ag nanowire (bright in the middle) perpendicular to the graphene stripe. The curve in the center shows the I_{sd} current as a function of time and temperature, showing a dramatic drop in the current upon etching if the channel. The curve in the right shows the I_{sd} as a function of the voltage at the gate (V_{gate}). The curve measured at room temperature (black) shows the neutrality point around V_{gate}=0V. Upon heating, the metal nanowire has an n-type doping effect of the graphene (the neutrality point shifts to negative values). Heating above 320° C. completes the catalytic etching and thus the current drops to zero.

FIGS. 4A-H provide graphene nanogap electrodes: (a)-(c) Optical microscope images showing the devices before, (a), and after metal deposition (b)-(c). (d)-(e) Show I_{d}-V_{d} and Id-V_{g} of a graphene stripe on Si/SiO₂(90 nm) substrate, both measured on the graphene device shown in the SEM image in (f). The linear I_{d}-V_{d} indicates an Ohmic characteristic in the measured voltage regime. The I_{d}-V_{g} shows a typical ambipolar behavior with charge neutrality point (Dirac point) at +14V. This characteristic indicates a p type behavior of graphene which will be usually observed due to hole doping from oxygen while exposing into the ambient conditions. (g)-(h) Isd-Vsd curve measured for a device after catalytic etching, as shown in the SEM image in (h), showing a disconnected device due to the formation of the nanogap.

FIG. 5 demonstrates filling the graphene nanogap by low temperature (˜350° C.) metal-organic chemical vapor deposition (MOCVD) of WS₂ (tungsten disulfide, a member from the transition metal dichalcogenide family).

FIG. 6 shows WS₂-based photodetectors made on different graphene nanogap electrodes. Left: Photocurrent as a function of laser power for three different nanogaps (70, 180 and 540 nm). Right: Photoresponsivity (PR), which reflects the photodetector sensitivity to the incident light, can be expressed as, PR=Iₚ P_{d}×_{eff}, where, Iₚ, is the photocurrent, P_{d} is the laser power density, and A_{eff} is the device active area. The PR is plotted for the same devices in the left and for a 10 μm device made by standard photolithography for comparison. It can be seen that the photodetector performance is improved with the reduction of the channel length.

### DETAILED DESCRIPTION OF EMBODIMENTS

### Experimental

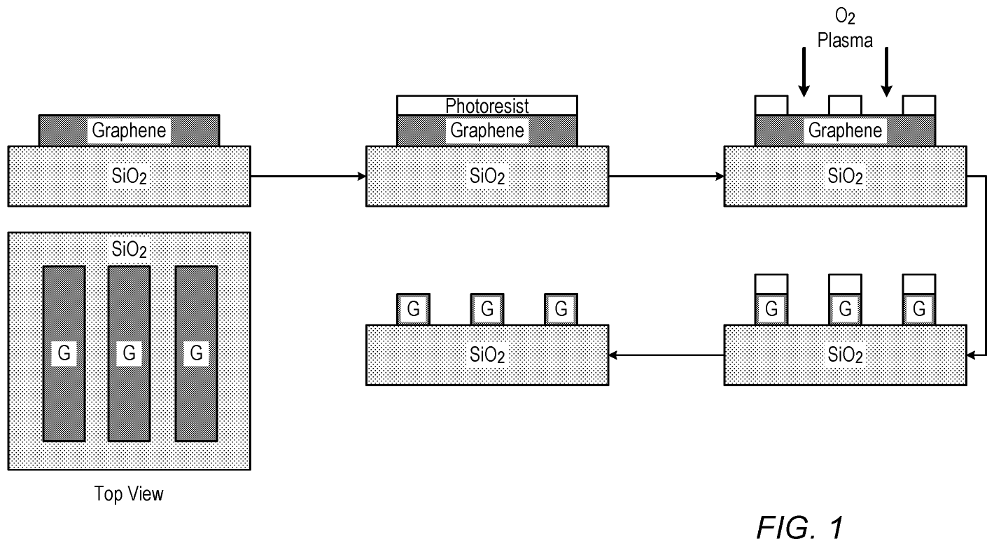

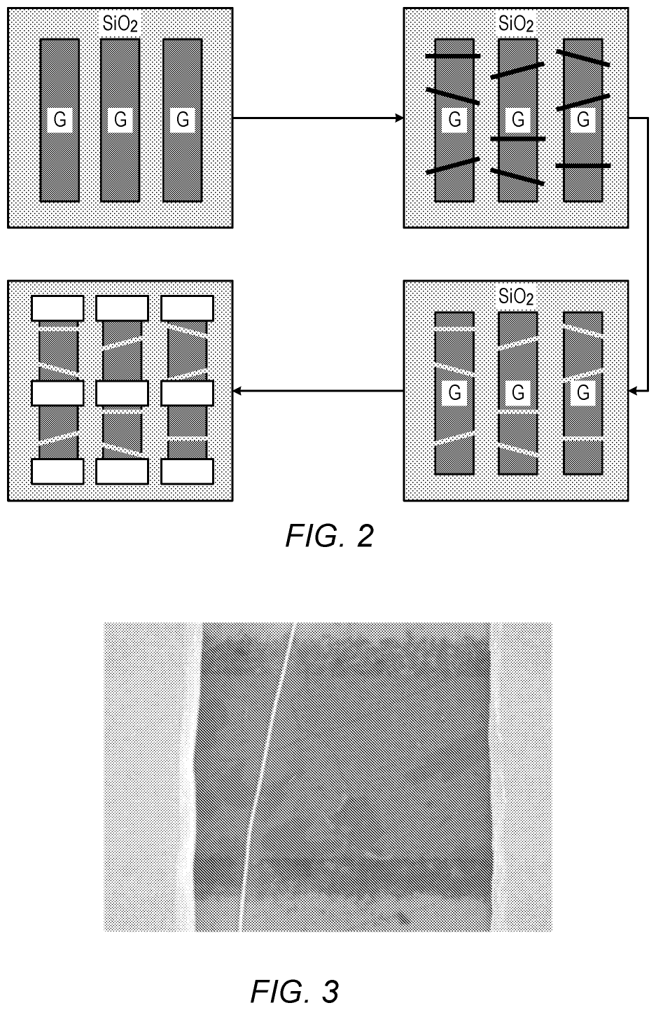

Single-layer graphene (SLG) and multi-layer graphene (MLG) were grown by a CVD technique using methane as a starting precursor in hydrogen and argon environment, and were transferred onto 285 nm SiO₂\Si substrate. The graphene was patterned by conventional optical photolithography to an array of microscale stripes pattern of 5 um . The FET channels were fabricated by catalytic etching process using silver nanowires (Ag NWs) from a commercial solution deposited directly on the graphene stripes. The NWs were aligned across the graphene stripes and the samples were annealed during the CE process, followed by the removal of the silver using HCl-I₂ solution. Metal electrodes were deposited on the substrate followed by deposition of WS₂ as the channel material. The process is depicted in FIGS. 1-2.

### Experimental—Supporting Information

### Graphene Preparation

Single-layer graphene (SLG) and multi-layer graphene (MLG) were grown by LPCVD and APCVD, respectively, using methane as a starting precursor in hydrogen and argon environment.

For SLG growth a 25 μm thick copper foil (PubChem, purity 99.8%, CAS: 7440-50-8) was used as a catalyst and for MLG growth a 25 μm nickel foil (Goodfellow, purity 99.9%, CAS: 7440-02-0) was used as a catalyst. The foils were pre-treated with glacial acetic acid for approximately 30 minutes in order to improve surface roughness and reduce oxides, and were blow dried by nitrogen atmosphere before inserting it to a 1-inch quartz tube of the CVD system.

For SLG growth, the furnace was heated to a temperature of 1050° C. at rate of 21° C./min with 2 sccm hydrogen and 1 sccm argon atmosphere and was further annealed at 1050° C. for 30 minutes before growth. 7 sccm of methane was introduced into the system at growth stage, along with hydrogen and argon (flows remained unchanged) for 30 more minutes. The growth stage was carried out at pressure of ˜2×10⁻¹ torr.

For MLG growth, the furnace was heated to a temperature of 1020° C. at rate of 20.4° C./min with 20 sccm hydrogen and 5 sccm argon atmosphere and was further annealed at 1020° C. for 30 minutes before growth. 5 sccm of methane was introduced into the system at growth stage, along with hydrogen and argon (flows remained unchanged) for 60 more minutes. The system was rapidly cooled in hydrogen and argon atmosphere (flows remained unchanged).

The graphene was transferred onto a heavily-doped silicon wafer with 285 oxide layer. The SLG was transferred by a conventional PMMA technique, as the copper foil was etched by 1M ammonium persulfate solution. The PMMA was removed by acetone. The nickel foil was etched by 0.5M iron chloride solution and the graphene were rinsed by water and directly transferred on the silicon substrate.

### Deposition of Silver Nanowires and Catalytic Etch Process

The catalytic etch process was performed using IPA based Ag NWs commercial solution (Sigma Aldrich, liquid suspension in IPA, CAS: 7440-22-4). The NWs solution was diluted five times to its original concentration and was then drop-cast on the graphene\Si samples until the wafer was completely covered with solution, approximately 50 μL per 10×10 mm² wafer. After 1 minute the samples were tilted in order to align the NWs in a vertical direction, until the IPA was evaporated and only the NWs had remained. The wafer was gently rinsed with water by dipping the wafer into a small beaker, in order to remove IPA remains from the surface of the sample. The samples were put in ambient conditions in RT for at least 1 hour until full evaporation of the water.

The samples were placed inside a furnace heated quartz tube using a custom-made hollow stainless-steel rod. In order to measure the exact temperature of the process, a thermocouple was inserted from one edge of the rod into the other “spoon-like” edge, where the samples were placed, and then were rapidly heated by pushing the rod inside the heated tube. Next, the samples were rapidly cooled by pulling the rod with the samples outside the tube. The samples were annealed at different temperatures between 300-650° C. for different times between 1-45 minute until the process was optimized. For the SLG electrodes of the FET the channels were created by annealing the sample at 350° C. for 10 minutes.

After the CE process, the Ag NWs were etched in order to be removed from the sample using hydrochloric iodine solution, so that a clean channel will be achieved without interfering the electrical measurements. 12-HCl solution has been prepared from mixing 115 mg of I₂ powder with 5 ml 32% HCl. The powder was crushed by a ceramic spoon and the I₂-HCl mix was sonicated for 30 minutes. The remained powder chunks were filtered, and the solution was kept in a refrigerator for future use.

### Patterning by Photolithography

### Graphene Patterning Prior to CE Process

A conventional optical photolithography process was carried out in order to create an array of graphene thin stripes, using a positive mask. The graphene\Si samples were spin coated by hexamethyldisilazane (HMDS) in order to improve the adhesion between the photoresist and the sample. Afterwards, the sample was spin coated by a thin layer of AZ1518 photoresist (MicroChemicals, 4000 rpm, 1.71 μm layer thickness) and was pre-baked at 115° C. for 1.5 minutes. The photoresist was exposed to 45 mJ/cm² dose and was developed by AZ 726 MIF developer (Merck) for 40 seconds, followed by water rinse. Thereafter, oxygen plasma was used to etch the exposed areas of the graphene, leaving the stripes of graphene covered with photoresist. The photoresist was then removed by N-Methyl-2-pyrrolidone (NMP) (MicroChem), and CE process was carried out.

### Electrodes Patterning and Metal Deposition

A conventional optical photolithography process was carried after CE process and silver remove for electrodes patterning, using a negative mask. The samples were spin coated by LOR resist (Kayaku Advanced Materials) and prebaked at 180° C. for 5 minutes in order to receive sharp and more accurate edges of the pattern. Afterwards, the sample was spin coated by a thin layer of AZ5214 photoresist (MicroChemicals©) (3000 rpm, 1.4-1.5 μm layer thickness) and was pre-baked at 110° C. for 1.5 minutes. The photoresist was exposed to 15 mJ/cm² dose followed by reversal bake at 120° C. for 2 min. The sample was then overexposed to 200 mJ/cm² and was developed by AZ 726 MIF developer (Merck) for 60 seconds, followed by water rinse. Thin metal film consisted of 5 nm Titanium followed by 80 nm Gold, was deposited on the pattern using electron beam evaporator, and the photoresist was lifted-off with NMP and acetone, revealing metal electrodes on the previously exposed areas.

### Deposition of Channel Material

Low-temperature growth of WS₂ directly onto the nanogap graphene electrodes, in order not to damage the sample using the MOCVD technique. Also, temperature of ˜400° C. and below gives us an advantage of semiconductor industrial compatibility. In the growth, DTBS or H₂S were used as the sulfur source and W(CO)₆ was used for the source of the metal W. In a typical experiment, 8.2×10⁻⁴ mol/min of DTBS and 3.28×10⁻⁷ mol/min of W(CO)₆ were flown inside a 3-inch quartz tube MOCVD system. The growth was carried out at 420° C. with an argon flow of 100 sccm for 2 hours. We also successfully carried out the WS₂ growth at lower temperature (375° C.) using H₂S as the S source, with 1sccm of flow.

### Electrical and Photoresponse Measurements

Here, Metal pads are deposited on graphene electrodes appropriately by Optical lithography (MA6) or electron beam lithography (Raith). These metal pads were used to connect external circuits to measure the electrical characterization of as grown WS2 on graphene electrodes.

The fabricated chip containing photodetectors were vacuum annealed (2×10⁻⁶ mbar) at 200° C. for overnight to improve the contact between Graphene/WS₂ and Graphene/Ti/Au. The chip containing devices were loaded in Linkam stage (HFSWV350-PB4) which has electrical probes to measure I-V in different temperature under air/vacuum environment. All measurements such as FET and photoresponse were performed between room temperature and 350° C. in ambient/vacuum condition using a semiconductor analyzer (Agilent B1500). For photoresponse, a green laser of wavelength 532 nm was used with 50× objective lens in Horiba laser Raman spectrometer. All photocurrent measurements were carried out with a sampling time of 10 ms, and an applied voltage between drain and source of 1 V.

Here, Metal pads are deposited on graphene electrodes appropriately by Optical lithography (MA6) or electron beam lithography (Raith). These metal pads were used to connect external circuits to measure the electrical characterization of as grown WS₂ on graphene electrodes.

The fabricated chip containing photodetectors were vacuum annealed (2×10⁶ mbar) at 200° C. for overnight to improve the contact between Graphene/WS₂ and Graphene/Ti/Au. The chip containing devices were loaded in Linkam stage (HFSWV350-PB4) which has electrical probes to measure I-V in different temperature under air/vacuum environment. All measurements such as FET and photoresponse were performed between room temperature and 350° C. in ambient/vacuum condition using a semiconductor analyzer (Agilent B1500). For photoresponse, a green laser of wavelength 532 nm was used with 50× objective lens in Horiba laser Raman spectrometer. All photocurrent measurements were carried out with a sampling time of 10 ms, and an applied voltage between drain and source of 1 V.

### Photoresponse Studies

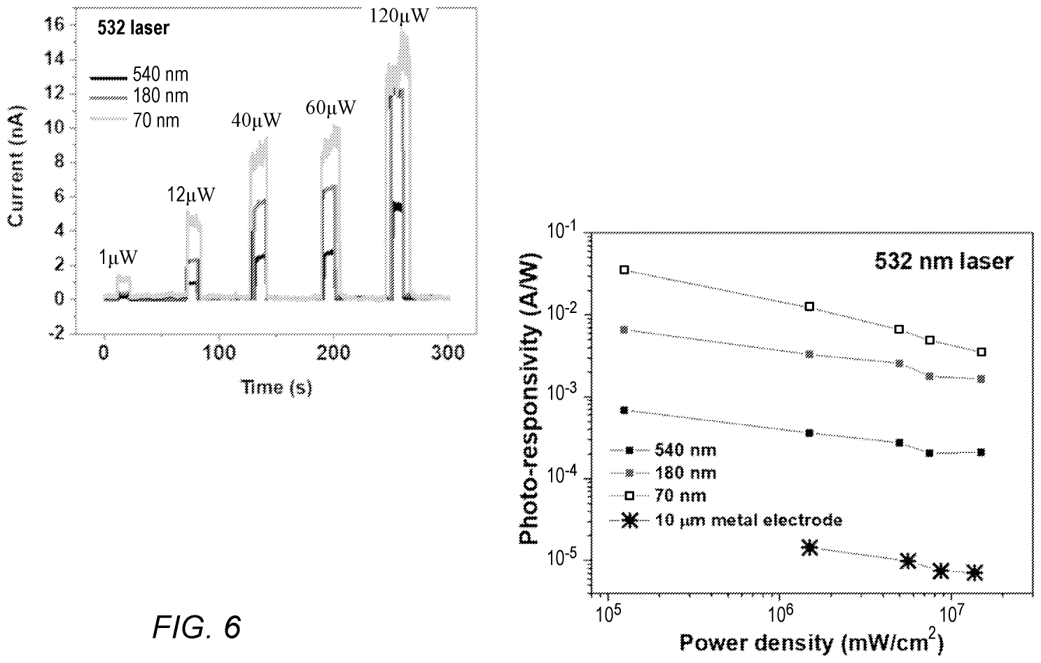

Photoresponse measurements were carried out from WS₂ on catalytically etched graphene devices with an excitation wavelength of 532 nm. Three devices (FIG. 6) were chosen with the channel length 540 nm, 180 nm and 80 nm. These channels were created by Ag nanowire during catalytic etching. FIG. 6 shows the photocurrent as a function of time, exhibiting the on/off behavior of the device with increasing effective laser powers (from 1.05 μW to ˜120 μW). The estimated photocurrent (Ip=I_{light}−I_{dark}) manifests up to 10² times larger than the dark current when the effective laser power reaches to ˜120 μW for 70 nm devices.

Responsivity, and external quantum efficiency (EQE) are additional figures of merit for a photo detector. Responsivity (R), which reflects the photodetector sensitivity to the incident light, can be expressed as, R=Iₚ P_{d}×A_{eff}, where, Iₚ, is the photocurrent, P_{d} is the laser power density, and A_{eff} is the device active area. It is to be noted that the R-value decreases when increasing the laser power density. This can be explained in terms of saturation of the carrier generation when increasing light intensity and the enhanced recombination and trapping in the interface between the substrate and graphene/WS₂ devices. Comparison between the devices of different channel width show the smaller the channel length yields higher photo response. This behavior might be associated with the effective extraction of charges while reducing the channel length.

### Results and Discussion

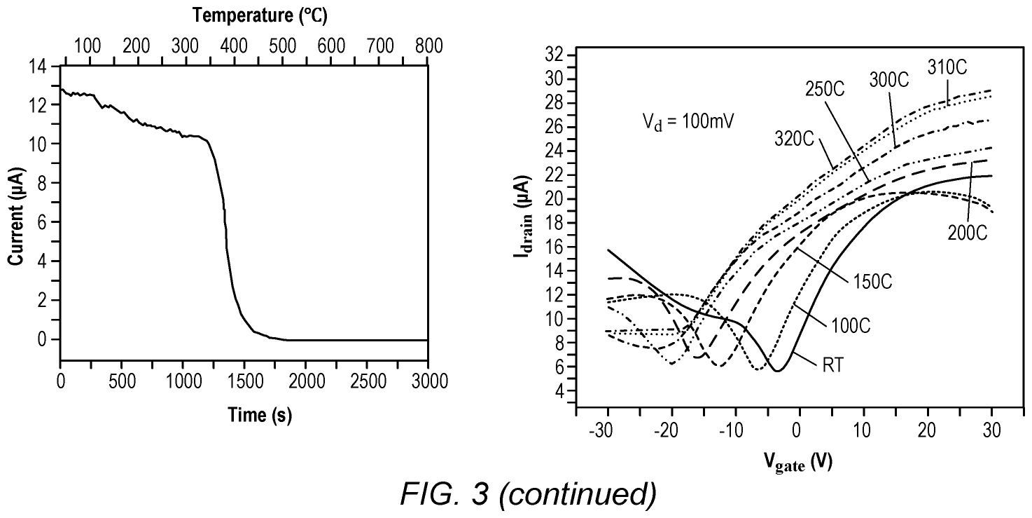

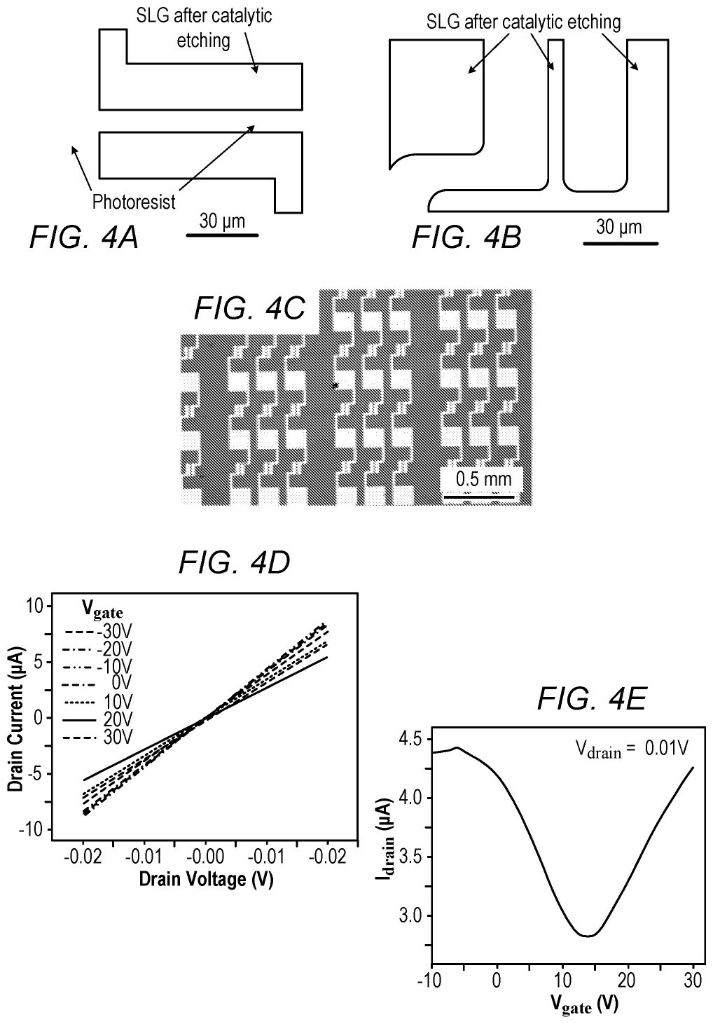

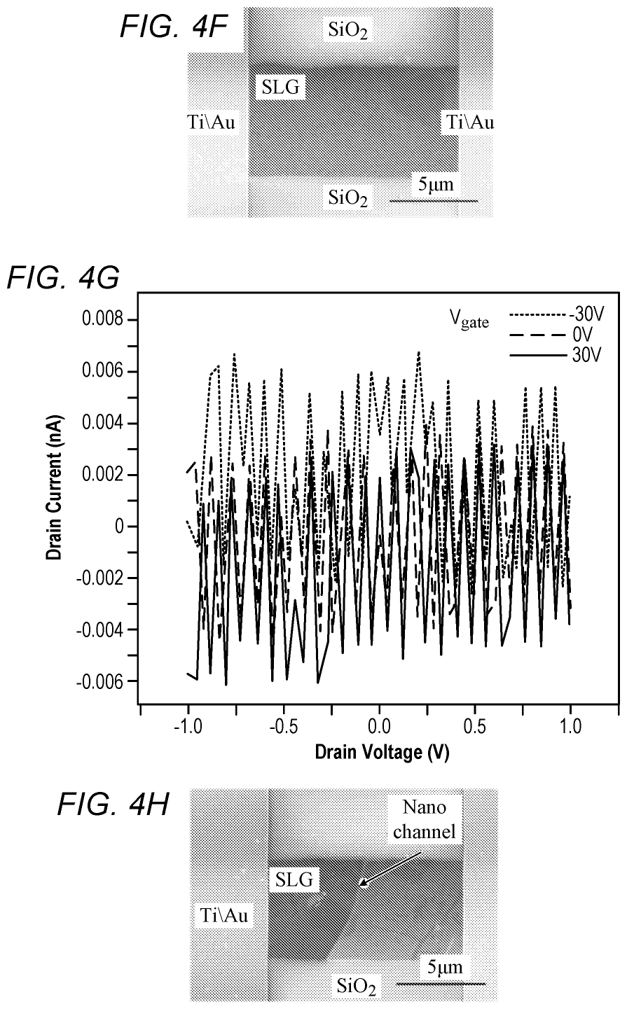

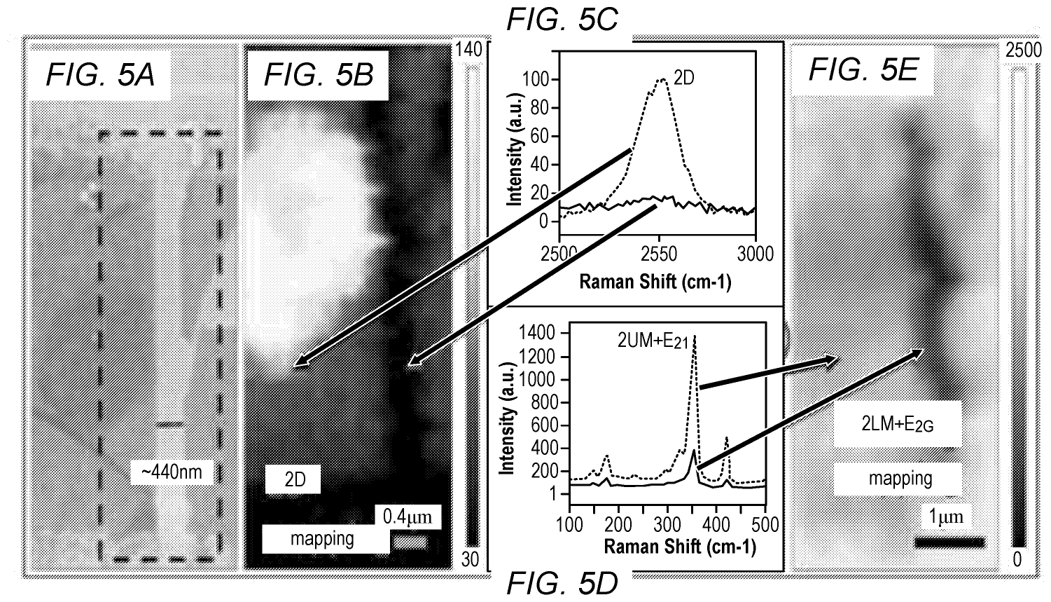

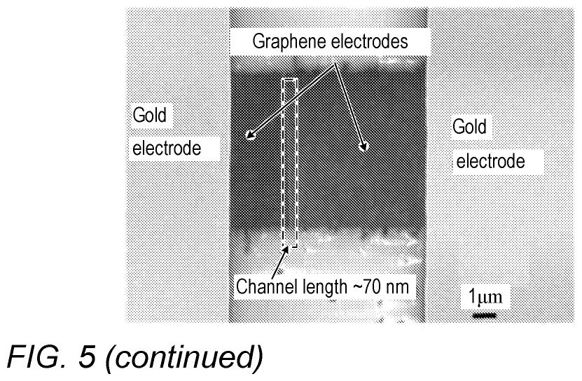

In order to in-situ study the catalytic etching of the graphene stripe by the Ag NW, electrical measurements were performed in a special cell while heating the device in air atmosphere. FIG. 3 shows the results of the in-situ measurements. The device consists of a graphene stripe with lithographic patterned electrodes, as shown above, and a Ag NW perpendicular to it. FIG. 3 shows an SEM micrograph of the Ag nanowire deposited on the graphene device. The transient current measured while increasing temperature as shown in FIG. 3 (center). The current reduced drastically while temperature approaching in to 350° C. In the Id-Vg measurements (FIG. 3) the device shows ambipolar characteristics. While comparing graphene the Dirac point marginally moved towards negative side for the Ag nanowire modified graphene. This can be due to electron injection into graphene through Ag⁺ from surface oxidation of silver nanowire. While increasing temperature this oxidation increased which makes the system to become more n type. Above 300° C. the ambipolar characteristics changed into n-type behavior. Further increasing the temperature above 330° C. makes the system behaving like an open circuit. This indicates that around ˜350° C. graphene is catalytically etched by Ag nanowire. Therefore, 350° C. was used for the catalytic etching-based devices in this study. It is noted that rapid heating causes a sharp etching in the graphene.

1-60. (canceled)

61. A process for fabricating a device comprising an ultra-short gap between a pair of electrodes, each electrode comprising or consisting of a single-layer or a few-layer graphene, the process comprising forming a lateral channel in a graphene strip being a single-layer or a few-layer graphene strip, wherein the channel is formed by a nanomaterial-induced catalytic etching.

62. The process according to claim 61, the process comprising:
forming a graphene strip on a substrate material, optionally being a SiO₂/Si substrate,
forming the lateral channel in the graphene strip by a nanomaterial-induced etching of the strip; and
depositing in said channel an active material.

63. The process according to claim 62, wherein the active material is a transition metal dichalcogenide (TMDC).

64. The process according to claim 61, wherein forming the lateral channel comprises placing a nanoparticle catalyst on the graphene strip under conditions permitting its etching at any point of interface with the graphene material.

65. The process according to claim 64, wherein the nanoparticle catalyst is a metal, a metal oxide, a metal alloy, a metal halide, a metal chalcogenide, a carbon halide or a carbon chalcogen nanomaterial.

66. The process according to claim 61, wherein the nanomaterial-induced catalytic etching comprises at least one nanoparticle selected from a spherical nanoparticle, a nanorod, a nanotube and a nanowire.

67. The process according to claim 66, wherein the nanoparticles having a diameter, a width and/or a length between 1 and 100 nm.

68. The process according to claim 61, comprising depositing on the graphene strip or in a vicinity thereof a nanoparticle and subsequently heating the strip to a temperature between 350° C. and 600° C., in presence of air or hydrogen/argon gas, to thereby cause etching of the graphene material.

69. The process according to claim 61, comprising treating a graphene microstrip, having at least one metallic nanoparticle provided on an edge region of the strip, at a temperature between 350 and 600° C., under an atmosphere of hydrogen gas, to cause local gasification of the graphene at the interface with the nanomaterial.

70. The process according to claim 61, comprising depositing in the channel an active material or a thin film formed of a 2D material, a 1D material or a 0D material.

71. The process according to claim 70, wherein the 2D material is a transition metal dichalcogenide (TMDC) material.

72. The process according to claim 71, wherein the TMDC is deposited by chemical vapor deposition (CVD) or metal organic chemical vapor deposition (MOCVD).

73. The process according to claim 71, wherein the TMDC is a semiconductor material of the form MX2, wherein M is a transition-metal atom, and X is a chalcogen atom.

74. The process according to claim 71, wherein the TMDC is selected from MoS₂, WS₂, MoSe₂, WSe₂, and MoTe₂.

75. A short channel transistor device comprising a source electrode and a drain electrode, each of the source and drain electrodes comprising or consisting of a single-layer or a few-layer graphene; an etched nanogap disposed between the electrodes having a width ranging between 1 nm and 100 nm and comprising an active material.

76. The device according to claim 75, the device being a nanofabricated transistor device comprising at least two longitudinally oriented graphene segments, each segment having at least one end proximal to an end of another graphene segment, wherein the gap or distance between each two proximate ends is a nanogap, wherein the nanogap is formed by the nanomaterial-induced etching and wherein the nanogap comprising a transition metal dichalcogenide.

77. The device according to claim 75 fabricated by a process comprising forming a lateral channel in a graphene strip by the nanomaterial-induced catalytic etching, the channel being a nanogap.

78. The device according to claim 77, wherein the process comprises:
forming a graphene strip on a substrate material;
forming the lateral channel in the graphene strip by the nanomaterial-induced etching of the strip; and
depositing in said channel an active material.

79. The device according to claim 75, wherein the active material is selected from 2D materials, 1D materials and 0D materials.

80. The device according to claim 75 being a channel device photodetector or sensor comprising a pair of graphene nanogap electrodes, the electrodes being spatially separated by a nanogap formed by a metal or a metal oxide nanoparticle-induced etching of a graphene surface.
